(19) United States
(12) Patent Application Publication
(10) Pub. No.: US 2016/0086864 A1
(43) Pub. Date: Mar. 24, 2016

(54) MOVABLE GAS NOZZLE IN DRYING MODULE

(71) Applicant: Lam Research Corporation, Fremont, CA (US)

(72) Inventors: Andreas Fischer, Castro Valley, CA (US); Thorsten Lill, Santa Clara, CA (US); David Trussell, Fremont, CA (US)

(21) Appl. No.: 14/495,693

(22) Filed: Sep. 24, 2014

(51) Int. Cl. H01L 21/66; H01L 21/67; H01L 21/02

(52) U.S. Cl. CPC H01L 22/26; H01L 21/02057; H01L 21/67051; H01L 21/67069; H01L 21/67155; H01L 22/12

(57) ABSTRACT

Provided herein are methods and apparatuses for cleaning wafers by coating an active surface of the wafer with a film of water to clean the wafer, delivering gas from a gas nozzle to the center of the active surface to break a film of water on the active surface to form a wet-dry boundary while spinning the wafer, and moving the gas nozzle radially outward from the center to the edge of the active surface of the wafer by following the wet-dry boundary. Tracking devices, such as cameras or charge-coupled devices, and systems may be used with an apparatus for cleaning wafers by tracking the wet-dry boundary on the wafer to move the gas nozzle to follow the wet-dry boundary. Cleaning apparatuses provided herein may be integrated with etching tools.

### BACKGROUND

Wafer cleaning methods and apparatuses are used in semiconductor fabrication processes to provide clean wafer surfaces at the conclusion of processing and in preparation for subsequent processing. In particular, wafer cleaning after etching processes are often used prior to or after deposition of layers to reduce particles and contamination on the wafer surface.

### SUMMARY

Provided herein are methods of cleaning and drying wafers. One aspect involves a method of cleaning wafers by coating an active surface of the wafer with a film of water to clean the wafer, delivering gas from a gas nozzle to the center of the active surface to break a film of water on the active surface to form a wet-dry boundary while spinning the wafer, and when the film of water is broken, moving the gas nozzle radially outward from the center to the edge of the active surface of the wafer by following the wet-dry boundary. In some embodiments, the gas is nitrogen.

In some embodiments, water is also delivered to a back surface of the wafer while water is delivered to the active surface of the wafer. The water may be delivered to the back surface of the wafer by flowing water at a flow rate of about 0.5 l/min.

The water nozzle may be moved into a water delivery position for delivering the water to the center of the active surface of the wafer without moving the gas nozzle to the water delivery position. The water nozzle may be moved away from the water delivery position, and the gas nozzle may be moved into a gas delivery position for delivering the gas to the center of the active surface.

The gas delivery position and the water delivery position may be at substantially the same location. The gas delivery position and the water delivery position may direct a jet of gas or jet of water, respectively, to the center of the wafer.

In some embodiments, coating the active surface of the wafer with the film of water includes flowing water at a flow rate of about 1.5 l/min. The water may be delivered to the center of the wafer for a time between about 20 seconds and about 30 seconds. The wafers may also be cleaned at atmospheric pressure. In some embodiments, delivering the gas includes flowing the gas at a flow rate between about 2 l/min and about 20 l/min.

In various embodiments, a tracking device detects the wet-dry boundary and provides a feedback loop to move the gas nozzle in response to the moving wet-dry boundary.

Another aspect may involve an apparatus for cleaning wafers including a cleaning module, which includes: a water nozzle, a gas nozzle, a wafer holder for holding the wafer and rotating the wafer during cleaning, and a tracking device oriented for detecting the wafer surface while the wafer is held and rotated on the wafer holder; and a wafer imaging system, which includes image analysis logic for detecting a wet-dry boundary on the wafer surface using optical properties of the surface, and a feedback mechanism for moving the gas nozzle in response to data collected from the tracking device.

The gas nozzle may be pivoted from a point outside the edge of the wafer. The water nozzle may be pivoted from a point outside the surface of the wafer.

In some embodiments, the cleaning apparatus is integrated with an etching apparatus, the etching apparatus including one or more process chambers for etching patterns on wafers and a wafer transfer tool. In some embodiments, the etching apparatus is a platform or cluster tool. The optical properties may include polarization, or reflection, or color and brightness.

These and other aspects are described further below with reference to the drawings.

### BRIEF DESCRIPTION OF THE DRAWINGS

FIGS. 1, 2, 5, and 6 are process flow diagrams depicting operations in accordance with various embodiments.

FIGS. 3 and 4 are schematic depictions of the top view of an apparatus during operations in accordance with various embodiments.

FIG. 7 is a schematic depiction of a cleaning and drying module in accordance with various embodiments.

FIG. 8 is a schematic representation of a tool including an apparatus in accordance with various embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Etching wafers often results in particles or contaminants on the surface of the wafer, which, if not removed, may cause damage to the semiconductor device. Example contaminants include halogen-containing materials remaining on the wafer surface after an etch process. Examples of such materials include halogens, which may form halogen hydrates upon exposure to air. These halogen hydrates are defects which may cause yield loss on a device wafer. Thus, after etching processes, wafers are often rinsed and dried on a tool separate from the wafer etch tool to remove any such contaminants and prepare the wafer for subsequent processing, such as deposition processes.

In conventional cleaning techniques, a wafer is provided for cleaning. The wafer is held by a wafer chuck and spun during the cleaning and drying process. Deionized water is delivered to the wafer to rinse the wafer, and then gas is introduced to support drying the wafer. As used herein, the term “water” may be construed as deionized water or other liquid suitable for cleaning partially-fabricated semiconductor devices. A combination of the gas blow dry and the centrifugal force on the water on the wafer dries the wafer. However, the gas nozzle is fixed during drying operations, so watermarks may form due to uneven drying and reliance on centrifugal forces. Droplets may still remain especially near the wafer center where centrifugal forces are small after a conventional wafer spin-rinse-dry process.

In some conventional techniques, the water and gas nozzle are in a fixed joint nozzle, pointing towards the center of the wafer. Since the nozzles are fixed and co-located, only the water jet or the gas jet but not both can be adjusted to hit the wafer center at any given time. The locations of the gas and water jets cannot be controlled independently. Thus, while the nozzle may be positioned farther away from the center of the wafer to prevent splashing from the water jet, such a position may be too far for the gas jet to effectively blow dry the wafer. To the extent that the joint nozzle may be moved, the water and gas nozzles are moved together and thus it is impossible for both to be pointing towards the center of the wafer. The joint nozzle also has limited movement.

Provided herein are methods and apparatuses of cleaning wafers using independently controlled water and gas nozzles, optionally with a tracking device and system to control moving the gas nozzle during a drying process. Methods involve rinsing a wafer and blow-drying a surface with a gas jet (such as nitrogen), using a rotatable gas pipe for gas delivery located above the wafer with the nozzle mounted at the far end. The nozzle may be oriented to maintain a normal angle between the gas jet emanating from the nozzle and the wafer surface, where a wet-dry boundary formed which moves radially outward. Wafers are dried more evenly and watermarks are reduced or eliminated. In certain embodiments, apparatuses provided herein include etch tools with integrated cleaning modules, where cleaning modules include a tracking device with feedback loop to move the gas nozzle relative to a moving wet-dry boundary formed on the wafer during the drying process.

### Method

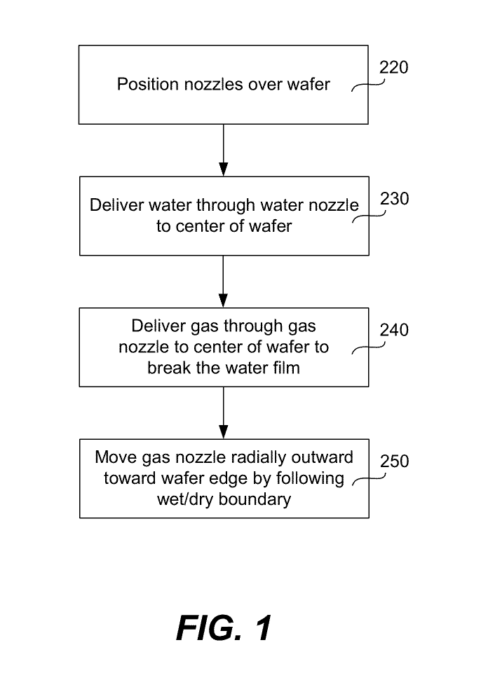

FIG. 1 is a process flow diagram depicting various operations in accordance with the disclosed embodiments. Prior to transferring the wafer into a cleaning module, the water nozzle may be oriented such that the opening on the end of the water nozzle is positioned away from where a wafer is to be placed in the cleaning module. After the wafer is installed for cleaning, nozzles are positioned over the active surface of the wafer. See operation 220. In some embodiments, the wafer was transferred from an etching station to the cleaning module using a tool transfer robot. The wafer may be held in place with wafer holders, which may include alignment and/or clamping members to hold the wafer during wafer spinning The wafer may be a silicon wafer, e.g., 200-mm wafer, 300-mm wafer, 450-mm wafer, including wafers having one or more layers of material such as dielectric, conducting, or semi-conducting material deposited thereon. The wafer may include features, such as features etched in a prior process. The nozzles may be a water nozzle for delivering a jet of deionized water, and a gas nozzle for delivering a gas, such as nitrogen or argon. The water or gas may be delivered through an opening at the end of the nozzle. In certain embodiments, a continuous drip of water is delivered to the water nozzle when not in use; a drip of about every two seconds may be used. The water nozzle drip may also be turned off as desired during any clean process in accordance with disclosed embodiments. In some implementations, both nozzles are independently controlled, such that the orientation of each nozzle may be set differently and the movement of one nozzle does not depend on the movement of any other nozzle. After the nozzles are positioned over the wafer, the process delivers water to the center of the wafer through the water delivery nozzle. See operation 230. The wafer may rotate about a central axis to deliver the water over the entire wafer surface thereby forming a film and cleaning the wafer. After the wafer has been cleaned, it is dried in two operations as shown in FIG. 1. First, a gas nozzle delivers a drying gas such as nitrogen to the center of the wafer where it breaks through the water film. See operation 240. Finally, a control system moves the gas nozzle radially outward toward the wafer edge by following the wet/dry boundary. See operation 250.

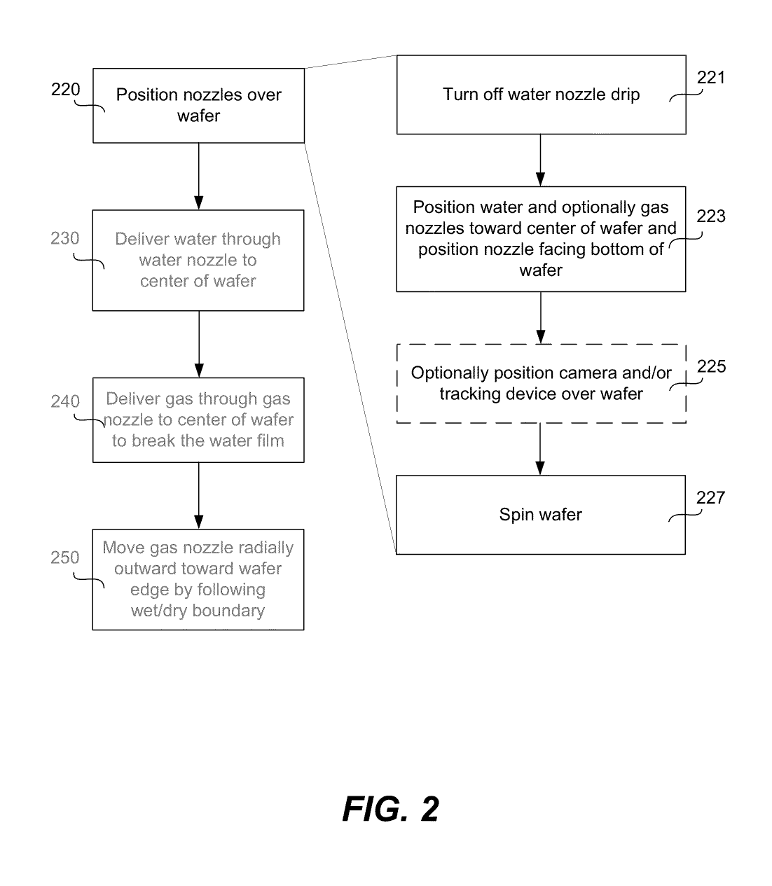

FIG. 2 is a process flow diagram depicting detailed operations for operation 220. In operation 221, the water nozzle drip is turned off so as to prevent water from dripping onto the wafer, which may spot the wafer. After the water nozzle drip is turned off, in operation 223, the water nozzle is positioned over the wafer to a wafer location such as the center of the wafer. The center of the wafer may be defined as any point within a circle having a radius of about 0.5 inches in the center point of the wafer. In some embodiments, the water nozzle opening may be directed to the center of the wafer. In some embodiments, the end of the water nozzle may be slightly off-center such that the water jet would hit the surface of the wafer in the center of the wafer at an angle, such as between about 20 to about 70 degrees, or about 45 degrees, with respect to the wafer normal.

In some embodiments, the gas nozzle is also positioned at substantially the same location as the water nozzle. In some embodiments, the location is the center of the wafer. As an example, nozzles pointing in substantially the same direction point their openings toward the center of the wafer within a circle having a radius of about 0.5 inches. The length of the gas nozzle may be longer than the water nozzle such that the gas nozzle is positioned at an angle with the end of the gas nozzle positioned directly above the center of the wafer. The gas nozzle may be mounted such that a normal angle is maintained between the direction of the gas emanating from the nozzle and the wafer surface. For example, the gas nozzle may point downwards such that the nozzle is perpendicular to the wafer plane, with a pivot point of the pipe (rotational mid-point) at a corner of the module.

During operation 223, a water nozzle may also be positioned under the wafer such that the bottom of the water nozzle is positioned to direct a jet of water to the center of the back surface of the wafer to clean the back surface.

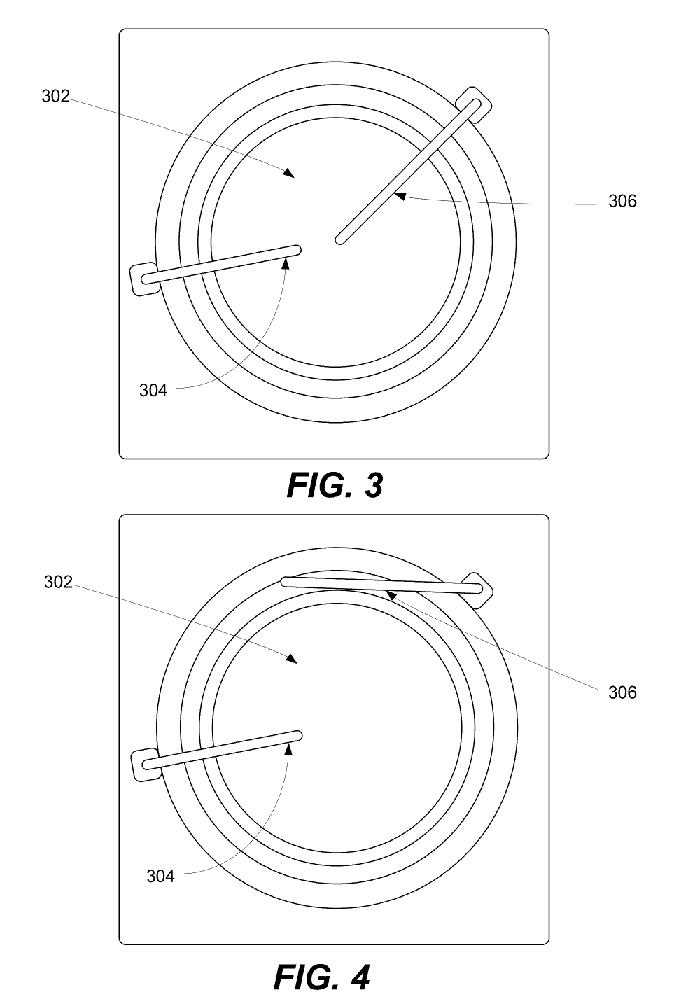

FIG. 3 is a schematic depiction of the top view of a cleaning module with a water delivery arm 304 and a gas delivery arm 306 each positioned over wafer 302 with a nozzle at its distal end (the far end disposed away from the pivot). As shown, both nozzles are positioned such that the water jet as projected from the water delivery arm 304 would be directed to the center of the wafer 302, and the nozzle of gas delivery arm 306 is positioned directly over the center of the wafer 302.

FIG. 4 is a schematic depiction of the top view of a cleaning module with gas nozzle 306 pivoted to the side of the wafer such that water nozzle 304 is directed to the center of the wafer. These nozzles may be moved after certain operations as described below. The term “pivot” as described herein means to rotate along an axis. For example, if FIG. 3 depicts the cleaning module before pivoting and FIG. 4 depicts the cleaning module after pivoting, gas nozzle 306 is pivoted such that it rotates along the axis, the axis being at the top right edge of the cleaning module depiction, and the gas nozzle 306 pivoting to move away from the center of the wafer 302. While this disclosure describes the nozzles as being pivoted in various operations, other methods of movement can be employed, such as translation or rotation.

In operation 226, a camera and/or other sensing device, such as a charge-coupled device (CCD) is positioned over the wafer. In some embodiments, the device is positioned at a later time. Further discussion regarding the camera and/or sensing device is provided below.

In operation 227, the wafer holder spins the wafer such that the wafer rotates. The wafer holder may have a cam mechanism to apply a clamping force on the wafer as the wafer spins. In certain embodiments, the spinning speed is about 300 rpm up to about 3000 rpm. Note that the wafer continues to spin throughout operations 230-250.

Returning to FIG. 1, after the nozzles are positioned, in operation 230, water is delivered through the water nozzle to the center of the wafer. Water may be delivered from both the water nozzle facing the active surface of the wafer and the water nozzle facing the back side of the wafer at the same time.

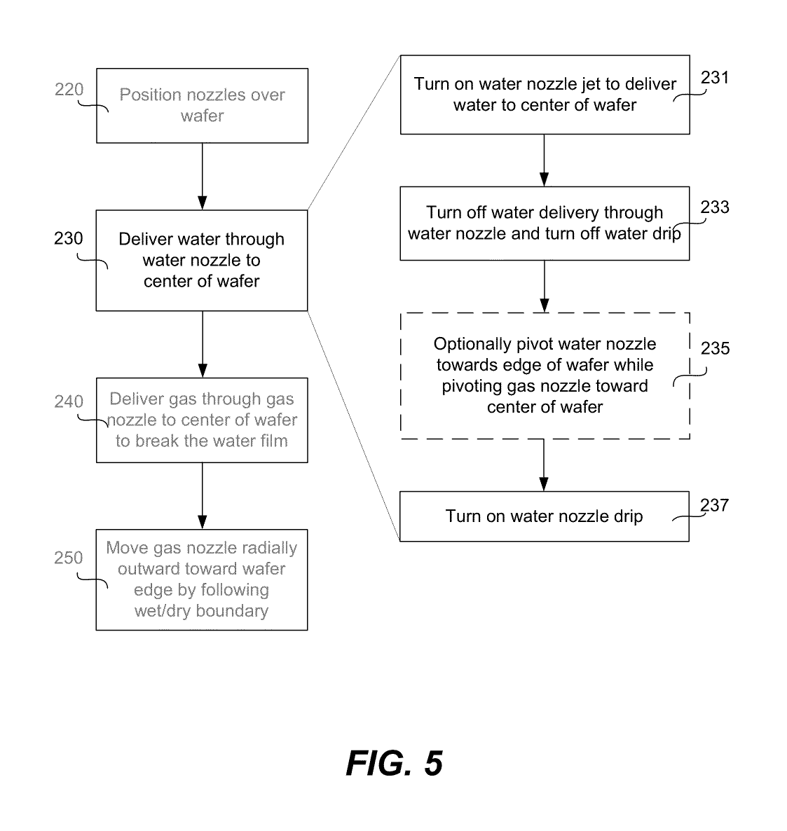

FIG. 5 is a process flow diagram depicting detailed operations for performing operation 230. In operation 231, the water nozzle jet is turned on to deliver water to the center of the wafer. In some embodiments, a thin film of water is covered onto the surface of the wafer in operation 231. In some embodiments, the thin film of water is covered on the active surface of the wafer. The flow rate of the water to the active surface of the wafer may be about 1.5 l/min, while the flow rate of the water to the back side of the wafer may be about 0.5 l/min. The onset or starting point of operation 231 may be adjustable. In some embodiments, the active surface of the wafer may be rinsed with water for about 20 to about 30 seconds. Note that during operation 231, the wafer is continuously spinning, and thus substantially all of the water is flung out from the edge of the wafer during rinsing due to the centrifugal force acting on the water on the film. In operation 233, the water is turned off for both the top and bottom water nozzles, and the water drip is also turned off such that no water flows from the water nozzle. The bottom nozzle is turned off about 2 seconds prior to the turning off the top nozzle so as to prevent water flung from the back side of the wafer due to centrifugal force from overflowing onto the active surface of the wafer. Once the water jet is turned off, a thin film of water remains on the surface of the wafer.

In operation 235, the water nozzle may be optionally pivoted towards the edge of the wafer while the gas nozzle is pivoted to the center of the wafer to be in a position similar to that described in FIG. 4, except where gas nozzle 306 points to the center, and water nozzle 304 is pivoted past the edge of the wafer. In some embodiments, if both nozzles were positioned to the center as described above with respect to FIG. 3, then the water nozzle 304 may be pivoted to the edge of the wafer while the gas nozzle 306 remains in place. Note that the degree of rotation for the gas nozzle may be about 20 to about 120 degrees). In some embodiments, water nozzle 304 and gas nozzle 306 already positioned such as in FIG. 3 may not be moved in operation 236. If the nozzles are not moved, the water drip to the water nozzle 304 remains off while the wafer is dried. Water and gas nozzle positions may be programmed into a recipe for a controller. Note that the length of the water and gas nozzles may vary such that when they both pivot, the two nozzles will not collide. In some embodiments, one nozzle is pivoted while the other remains fixed. In some embodiments, both nozzles are pivoted at the same time.

In operation 237, the water nozzle drip may be turned on, provided that the water nozzle is not positioned over the wafer and no risk of bacteria growth exists.

Returning to FIG. 1, in operation 240, gas is delivered through the gas nozzle to the center of the wafer to break the thin film of water on the surface of the wafer. Any suitable inert gas may be used, such as nitrogen or argon. In various embodiments, nitrogen is used such that when the wafer surface is dried and exposed to nitrogen immediately after the film of water is removed, the surface of the wafer is protected from any unwanted oxidation. The gas also assists in drying the wafer. Once dried, the surface of the wafer is not susceptible to oxidation.

The gas is delivered directly to the center of the wafer because although the wafer is spinning and centrifugal forces may force water on the surface outward, the only part of the wafer surface that has no centrifugal force is the center of the wafer. The gas is delivered to the center until the film breaks from the center of the wafer, which may be about 1 second. Gas may be flowed at a flow rate between about 2 l/min and about 20 l/min, or at a flow rate of about 5 l/min. For higher flow rates, the gas is first flowed at about 1 l/min to about 5 l/min for about 1 second before increasing the flow rate so as to prevent splashing due to an initial gas burst at the center of the wafer. Once the film breaks, a wet-dry boundary forms on the surface of the wafer. The wet-dry boundary is defined as the boundary on the surface of the wafer separating the dried wafer surface from the wet wafer surface. In some embodiments, the wet-dry boundary is circular such that the center of the circle formed by the wet-dry boundary is the center of the wafer. Typically, the wet-dry boundary moves radially outward due to the centrifugal forces caused by the rotation of the wafer.

In operation 250, the gas nozzle moves radially outward toward the wafer edge, following the wet-dry boundary, which is also moving radially outward. Note that throughout operation 250, the gas nozzle continues to flow gas. The velocity of the gas nozzle movement and velocity of the wet-dry boundary movement depend on wafer rotation speed, the hydrophilicity and hydrophobicity of the wafer, and flow rate of the gas, among other possible parameters.

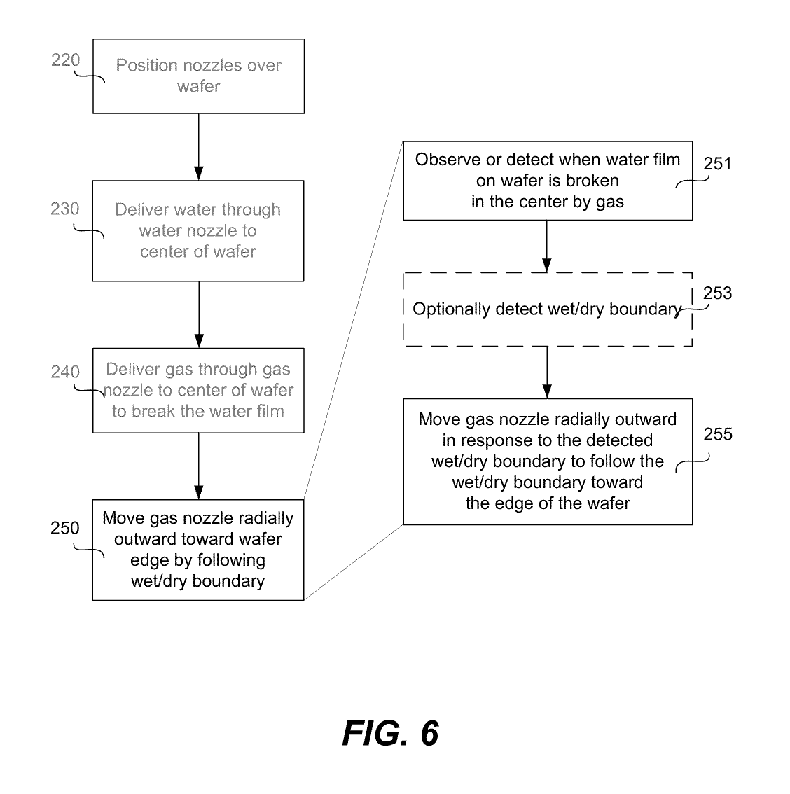

FIG. 6 is a process flow diagram depicting detailed operations for operation 250 in FIG. 1. In operation 251, the water film on the wafer is observed or detected to determine when the water film on the wafer is broken in the center by the gas delivery to the center of the wafer. In various embodiments, the edge of the film of water on the wafer is detected by a tracking device and corresponding wafer image analysis system.

The thin film of water may exhibit various optical properties, such that the surface of the wafer has differentiating characteristics between a dry surface and a wet surface. Whether the surface is wet or dry is detected by whether water is on the surface of the wafer at any given point. The tracking device may use any one or more of the following characteristics to detect when the water film is broken: color, brightness, reflection, and/or polarization.

For example, a charge-coupled device (CCD) camera may detect points on the wafer and evaluate the brightness or intensities for specific colors. A filter may be used on the camera such that the camera detects the filtered color. In some embodiments, two to three diodes, each with its own spectral sensitivity, may be used to track a specific color to narrow in on a range. Various techniques may be used for color detection. For example, U.S. patent application Ser. No. 13/928,141, filed on Jun. 26, 2013, titled “ELECTROPLATING AND POST-ELECTROFILL SYSTEMS WITH INTEGRATED PROCESS EDGE IMAGING AND METROLOGY SYSTEMS” and U.S. patent application Ser. No. 14/160,471, filed on Jan. 21, 2014, titled “METHODS AND APPARATUSES FOR ELECTROPLATING AND SEED LAYER DETECTION” describe image wafer analysis systems including cameras and/or CCD devices for detecting colors, and intensity or brightness.

In another example, the tracking device or camera may detect the light reflected from the surface of the water. Since the reflected light from the water surface is more polarized than light reflected from the dry wafer, a device can detect the relative amounts of polarization at two or more positions and thereby identify a wet-dry boundary. In some embodiments, film polarization may be detected by using a polarizing filter. Since silicon is transparent to light in IR but absorbs visible light, the detector may use these characteristics to determine whether the surface being detected contains water or dry silicon. Other wavelength specific discrimination techniques may be employed for different wafer surface materials.

After the tracking device detects when the water film is broken, the camera or other sensor and associated tracking device can further detect the wet-dry boundary moving radially outward due to the centrifugal force, in operation 253. As the boundary moves, the device sends position information to a controller controlling the operations of the process. Such information may include location coordinates of the wet-dry boundary, velocity of the wet-dry boundary movement, and other data. From this data, the controller determines the appropriate position of the gas nozzle such that nitrogen or other inert gas flows onto the surface immediately behind the moving boundary. The controller delivers positional control signals to the gas nozzle, thus implementing a feedback loop, such that the gas nozzle may move radially outward in response to the detected wet-dry boundary in operation 255. In another embodiment, the control of the nozzle may not be executed in a real time feedback loop. A computer and software can be used to record the location of the wet-dry boundary as a function of time and this information can be used to control the movement of the gas nozzle for the next wafer. Several curves can be recorded and averaged to create a golden curve used to control the movement of the nozzle. This would free up computing bandwidth for other tasks and reduce the cost of the computer. In various embodiments, the gas nozzle follows closely to the wet-dry boundary but maintaining a small distance, such as about a millimeter or less, behind the wet-dry boundary as the gas nozzle and the wet-dry boundary moves radially outward. This ensures that wafer surfaces that are dried are immediately exposed to nitrogen without being exposed to air to prevent oxidation. The delivered gas also helps in drying the surface, which increases the efficiency of the drying process and reduces the amount of time it takes for the wafer to be completely dry. Once the wet-dry boundary has reached the edge of the wafer, and the gas nozzle has passed the edge of the wafer, the entire wafer is completely dried. The wafer may then stop spinning, be returned to a homing position to allow a tool robot to collect the wafer, and transfer the wafer to another station or chamber or tool to continue subsequent processing.

### Apparatus

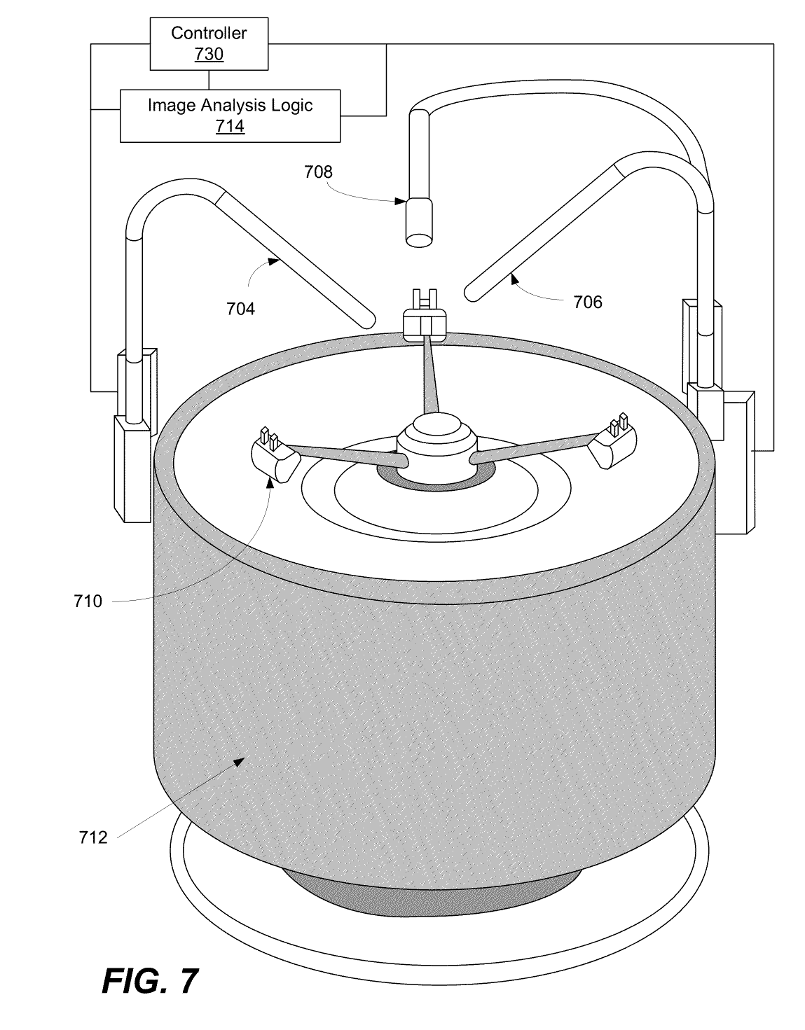

FIG. 7 provides an example of a spin-rinse-dry cleaning modules 712. The module 712 includes a wafer holder 710, gas nozzle 706, water nozzle 704, and a sensor 708. The gas nozzle 706 may be mounted at the tip of a rotatable gas pipe (or arm) for gas (e.g., N₂) delivery, located above the wafer such that the gas nozzle is mounted as its distal end and is oriented to maintain a normal angle between the gas jet emanating from the nozzle and the wafer surface, as well as the outward-moving wet-dry boundary. The gas nozzle 706 may be mounted at the end of the pipe with the nozzle 706 pointing down perpendicular to the wafer plane. The pivot point of the pipe (the rotational mid-point) may be connected to a stepper motor, which can actuate the angular position of the pipe within a few milliseconds. The pivot point may also be located outside the wafer area. The radial position of the gas nozzle above the wafer may be controlled via a controller and a feedback loop such that the hit point of the gas jet on the wafer surface follows the radial location of the outward-radially-moving wet-dry boundary in close proximity.

Each nozzle may include a pipe inside the nozzle, with an opening on the end of the nozzle. The water or gas may be delivered through the pipe and released through the opening on the nozzle. The nozzles may be attached to the module and may reach over onto the wafer surface from the point of attachment to the module.

A tracking device or sensor 708 may be used in tracking drying progress or tracking boundary (including feedback loop) via image analysis logic 714. A feedback loop may evaluate irregular liquid surface breakage and may be established by utilizing the sensor 708 mounted near the gas nozzle 706, such that the tracking device 708 senses the location of the wet-dry boundary and feeds the information via a controller to said stepper motor which adjusts the angular position of the gas nozzle 706. Feedback control of the nozzle movement may be programmed such that the radial location of the wet-dry boundary on the wafer is never overtaken by the position of the gas nozzle 706. The movement of the gas nozzle 706 can be controlled independently from the location of the water nozzle arm 704.

The tracking device 708 may be a camera, a linear CCD device, or other sensor. The tracking device 708 may include a stepper motor driven arm to track the wet-dry boundary or any part of the wafer. The tracking device 708 may be mounted near the gas nozzle 706 pointing downward. The tracking device 708 can detect the location of a wet-dry boundary, which may move radially outward from the center of the wafer to the edge of the wafer during the spin-dry process.

The controller 730, which may be connected to or include image analysis logic 714, is optionally connected to a computer. This logic determines the location of the boundary interface and the distance of the point of impact of the nitrogen jet and said boundary. This distance may be specified via process recipes. The imaging software may also detect irregular breaking of the liquid surface which can lead to watermarks. A warning or fault message can be issued in such an event. U.S. patent application Ser. No. 13/928,141, filed on Jun. 26, 2013, titled “ELECTROPLATING AND POST-ELECTROFILL SYSTEMS WITH INTEGRATED PROCESS EDGE IMAGING AND METROLOGY SYSTEMS” and U.S. patent application Ser. No. 14/160,471, filed on Jan. 21, 2014, titled “METHODS AND APPARATUSES FOR ELECTROPLATING AND SEED LAYER DETECTION” provide additional explanation and examples of algorithms used for image wafer analysis systems.

A suitable module 712 may include hardware for performing various process operations as well as a controller 730 having instructions for controlling process operations in accordance with the disclosed embodiments. The controller 730 will typically include one or more memory devices and one or more processors communicatively connected with various process control equipment, e.g., valves, wafer handling systems, etc., and configured to execute the instructions so that the apparatus will perform a technique in accordance with the disclosed embodiments, e.g., a technique such as that provided in the cleaning operations of FIG. 1. Machine-readable media containing instructions for controlling process operations in accordance with the present disclosure may be coupled to the controller 730. The controller 730 may be communicatively connected with various hardware devices, e.g., mass flow controllers, valves, vacuum pumps, etc. to facilitate control of the various process parameters that are associated with the cleaning operations as described herein.

In some embodiments, a controller 730 may control all of the activities of the module 712. The controller 730 may execute system control software stored in a mass storage device, loaded into a memory device, and executed on a processor. The system control software may include instructions for controlling the timing of gas flows, wafer movement, etc., as well as instructions for controlling the mixture of gases, the chamber and/or station pressure, the chamber and/or station temperature, the wafer temperature, the target power levels, the substrate pedestal, chuck, and/or susceptor position, and other parameters of a particular process performed by the module 712. The system control software may be configured in any suitable way. For example, various process tool component subroutines or control objects may be written to control operation of the process tool components necessary to carry out various process tool processes. The system control software may be coded in any suitable computer readable programming language.

In some embodiments, a controller 730 (which may include one or more physical or logical controllers) controls some or all of the operations of an etching chamber. The controller 730 may include one or more memory devices and one or more processors. The processor may include a central processing unit (CPU) or computer, analog and/or digital input/output connections, stepper motor controller boards, and other like components. Instructions for implementing appropriate control operations are executed on the processor. These instructions may be stored on the memory devices associated with the controller 730 or they may be provided over a network. In certain embodiments, the controller 730 executes system control software.

The system control software may include instructions for controlling the timing of application and/or magnitude of any one or more of the following chamber operational conditions: the mixture and/or composition of gases, chamber pressure, chamber temperature, wafer/wafer support temperature, wafer movement speed, and other parameters of a particular process performed by the tool. System control software may be configured in any suitable way. For example, various process tool component subroutines or control objects may be written to control operations of the process tool components necessary to carry out various process tool processes. System control software may be coded in any suitable compute readable programming language.

In some embodiments, system control software includes input/output control (IOC) sequencing instructions for controlling the various parameters described above. For example, each phase of a wafer clean process may include one or more instructions for execution by the controller 730. The instructions for setting process conditions for a rinsing phase may be included in a corresponding rinsing recipe phase, for example. In some embodiments, the recipe phases may be sequentially arranged, such that steps in a patterning process, such as the two-dimensional process, are executed in a certain order for that process phase.

Other computer software and/or programs may be employed in some embodiments. Examples of programs or sections of programs for this purpose include wafer positioning program, a process gas composition control program, a pressure control program, and a heater control program.

In some cases, the controller 730 controls gas concentration, and/or wafer movement. The controller 730 may control the gas concentration by, for example, opening and closing relevant valves to produce one or more inlet gas stream that provide the necessary reactant(s) at the proper concentration(s). The wafer movement may be controlled by, for example, directing a wafer positioning system to move as desired. The controller 730 may control these and other aspects based on sensor output (e.g., when power, pressure, etc. reach a certain threshold), the timing of an operation (e.g., opening valves at certain times in a process), or based on received instructions from the user.

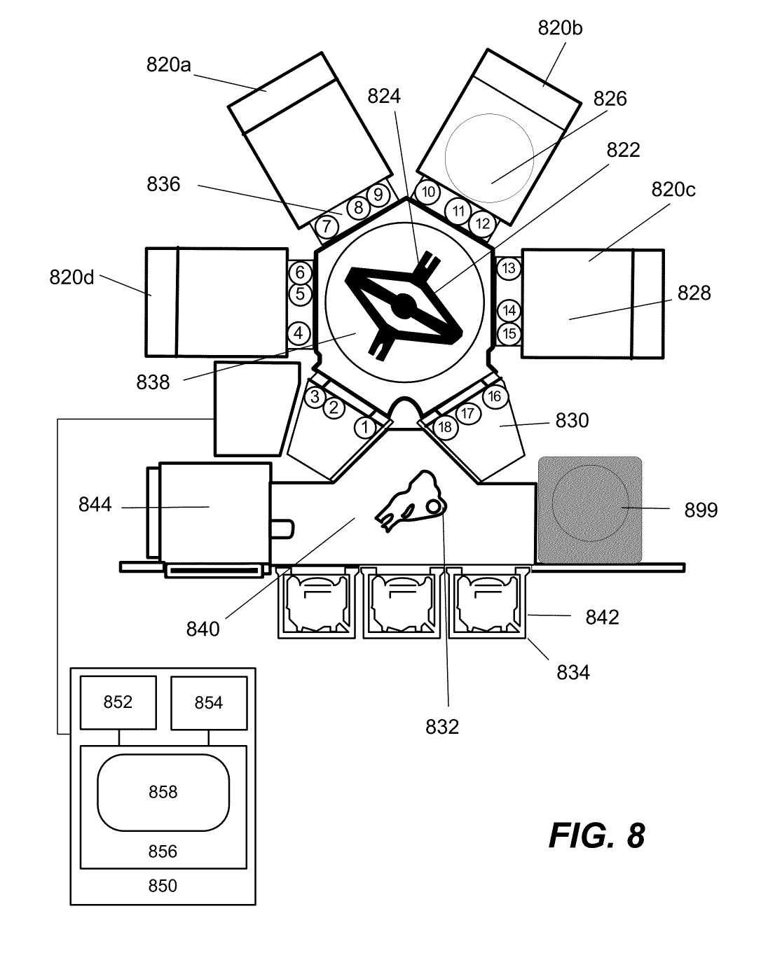

A Kiyo™ reactor, produced by Lam Research Corp. of Fremont, Calif., is an example of a suitable reactor that may be used to implement the techniques described herein. The reactor may be included on the vacuum side of a platform or cluster tool, such that the cleaning module as depicted in FIG. 7 is integrated on the atmospheric side of the tool, such as shown in FIG. 8. FIG. 8 depicts a semiconductor process cluster architecture with various modules that interface with a vacuum transfer module 838 (VTM). The arrangement of transfer modules to “transfer” wafers among multiple storage facilities and processing modules may be referred to as a “cluster tool architecture” system (or platform). Airlock 830, also known as a loadlock, is shown with the VTM (Vacuum Transfer Module) 838 with four processing modules 820a-820d, which may be individual optimized to perform various fabrication processes. By way of example, processing modules 820a-820d may be implemented to perform substrate etching, deposition, ion implantation, wafer cleaning, sputtering, and/or other semiconductor processes. One or more of the substrate etching processing modules (any of 820a-820d) may be implemented as disclosed herein, i.e., for depositing gap-fill AHM layers, depositing conformal films, etching patterns in single and two-dimensions, planarizing wafers, and other suitable functions in accordance with the disclosed embodiments. Airlock 830 and process module 820 may be referred to as “stations.” Each station has a facet 836 that interfaces the station to VTM 838. Inside each facet, sensors 1-18 are used to detect the passing of wafer 826 when moved between respective stations.

Robot 822 transfers wafer 826 between stations. In one embodiment, robot 822 has one arm, and in another embodiment, robot 822 has two arms, where each arm has an end effector 884 to pick wafers such as wafer 826 for transport. Front-end robot 832, in atmospheric transfer module (ATM) 840, is used to transfer wafers 826 from cassette or Front Opening Unified Pod (FOUP) 834 in Load Port Module (LPM) 842 to airlock 830. Module center 828 inside process module 820 is one location for placing wafer 826. Aligner 844 in ATM 840 is used to align wafers. A cleaning module 899 may be integrated to the apparatus such that robot 822 picks up wafers and transfers wafers in and out of the cleaning module 899. The cleaning module 399 may be similar to the example provided in FIG. 7.

In an exemplary processing method, a wafer is placed in one of the FOUPs 834 in the LPM 842. Front-end robot 832 transfers the wafer from the FOUP 834 to an aligner 844, which allows the wafer 826 to be properly centered before it is etched or processed. After being aligned, the wafer 826 is moved by the front-end robot 832 into an airlock 830. Because airlock modules have the ability to match the environment between an ATM and a VTM, the wafer 826 is able to move between the two pressure environments without being damaged. From the airlock module 830, the wafer 826 is moved by robot 822 through VTM 838 and into one of the process modules 820a-820d. In order to achieve this wafer movement, the robot 822 uses end effectors 824 on each of its arms. Once the wafer 826 has been processed, it is moved by robot 822 from the process modules 820a-820d to an airlock module 830. From here, the wafer 826 may be moved by the front-end robot 832 to one of the FOUPs 834 or to the aligner 844.

It should be noted that the computer controlling the wafer movement can be local to the cluster architecture, or can be located external to the cluster architecture in the manufacturing floor, or in a remote location and connected to the cluster architecture via a network. Controller 850 is an example of a controller that is used to control wafer movement, gas flows, temperatures and pressures, and other conditions. Controller 850 may include one or more memory devices 856, one or more mass storage devices 854, and one or more processors 852. Processor 852 may include a CPU or computer, analog, and/or digital input/output connections, stepper motor controller boards, etc. In some embodiments, controller 850 controls all of the activities of process tool 800. In some embodiments, cleaning module 899 has its own controller.

In some implementations, the controller 850 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 850, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller 850 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller 850 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller 850, in some implementations, may be a part of or coupled to a computer that is integrated with, coupled to the system, otherwise networked to the system, or a combination thereof. For example, the controller 850 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller 850 receives instructions in the form of data, which specify parameters for each of the processing steps to be performed during one or more operations. It should be understood that the parameters may be specific to the type of process to be performed and the type of tool that the controller 850 is configured to interface with or control. Thus as described above, the controller 850 may be distributed, such as by including one or more discrete controllers that are networked together and working towards a common purpose, such as the processes and controls described herein. An example of a distributed controller 850 for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller 850 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

In some embodiments, controller 850 controls the cleaning module 899 controller. Controller 850 executes system control software 858 stored in mass storage device 854, loaded into memory device 856, and executed on processor 852. Alternatively, the control logic may be hard coded in the controller 850. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 858 may include instructions for controlling the timing, mixture of gases, amount of sub-saturated gas flow, chamber and/or station pressure, chamber and/or station temperature, wafer temperature, target power levels, RF power levels, substrate pedestal, chuck and/or susceptor position, and other parameters of a particular process performed by process tool 800. System control software 858 may be configured in any suitable way. For example, various process tool component subroutines or control objects may be written to control operation of the process tool components necessary to carry out various process tool processes. System control software 858 may be coded in any suitable computer readable programming language.

In some embodiments, system control software 858 may include input/output control (IOC) sequencing instructions for controlling the various parameters described above. Other computer software and/or programs stored on mass storage device 854 and/or memory device 856 associated with controller 850 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 818 and to control the spacing between the substrate and other parts of process tool 800.

A process gas control program may include code for controlling gas composition and flow rates and optionally for flowing gas into one or more process stations prior to etching in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with controller 850. The user interface may include a display screen, graphical software displays of the apparatus and/or process conditions, and user input devices such as pointing devices, keyboards, touch screens, microphones, etc.

In some embodiments, parameters adjusted by controller 850 may relate to process conditions. Non-limiting examples include process gas composition and flow rates, temperature, pressure, plasma conditions (such as RF bias power levels), pressure, temperature, etc. These parameters may be provided to the user in the form of a recipe, which may be entered utilizing the user interface.

Signals for monitoring the process may be provided by analog and/or digital input connections of controller 850 from various process tool sensors. The signals for controlling the process may be output on the analog and digital output connections of process tool 800. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

Controller 850 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various embodiments described herein.

The controller 850 will typically include one or more memory devices and one or more processors configured to execute the instructions so that the apparatus will perform a method in accordance with the disclosed embodiments. Machine-readable media containing instructions for controlling process operations in accordance with the disclosed embodiments may be coupled to the controller 850.

### EXPERIMENTAL

### Experiment 1

An experiment was conducted to evaluate the rinsing and drying of a wafer with spin-drying from the wafer edge toward the center. A wafer with a blanket hydrophilic layer (continuous solid coating) was provided to a cleaning module. The wafer was spun and rinsed while spinning with deionized water for a time between 20 and 30 seconds. No gas was used to blow-dry the wafer. The wafer was spun at a speed of about 600 rpm for rinse and 1300 rpm for dry. After the water was delivered, the wafer dried from the outside in towards the center such that a wet-dry boundary moved from the outside edge of the wafer and moved to the center of the wafer. The centrifugal force in this experiment was observed as too high for purposes of an effective drying process in accordance with disclosed embodiments.

### Experiment 2

An experiment was conducted to evaluate the rinsing of a hydrophilic wafer and spin-drying in accordance with the disclosed embodiments. A wafer with a blanket hydrophilic layer was provided to a cleaning module. The wafer was spun and rinsed while spinning with deionized water for a time between 20 and 30 seconds. Nitrogen gas was delivered to blow-dry the wafer. The gas was directed to the center of the wafer to break the film, then moved outward to follow the wet-dry boundary formed until the wafer was dried. The gas was flowed at a flow rate of about 5 l/min. From a visual inspection, the wafer was effectively cleaned and dried, and little or no droplets formed on the surface of the wafer. The nitrogen gas helped protect the wafer from oxidizing and helped in blow-drying the surface.

### Experiment 3

An experiment was conducted to evaluate the rinsing of a hydrophobic wafer without spin-drying. A wafer with a blanket hydrophobic layer was provided to a cleaning module. The wafer was spun and rinsed while spinning with deionized water for a time between 20 and 30 seconds. No gas was delivered to blow-dry the wafer. The centrifugal force from the spinning wafer spin-dried the wafer, and from a visual inspection, the wafer was dried, but a few droplets of water formed on the surface of the wafer. This result suggested that an additional blow-dry process could be added to more fully dry the wafer surface.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method of cleaning wafers, the method comprising:
coating an active surface of the wafer with a film of water to clean the wafer,
delivering gas from a gas nozzle to the center of the active surface to break a film of water on the active surface to form a wet-dry boundary while spinning the wafer, and
when the film of water is broken, moving the gas nozzle radially outward from the center to the edge of the active surface of the wafer by following the wet-dry boundary.

2. The method of claim 1, further comprising delivering water to a back surface of the wafer while delivering water to the active surface of the wafer.

3. The method of claim 1, further comprising moving the water nozzle into a water delivery position for delivering the water to the center of the active surface of the wafer without moving the gas nozzle to the water delivery position.

4. The method of claim 1, further comprising moving the water nozzle away from the water delivery position, and moving the gas nozzle into a gas delivery position for delivering the gas to the center of the active surface.

5. The method of claim 1, wherein the gas delivery position and the water delivery position are at substantially the same location.

6. The method of claim 5, wherein the gas delivery position and the water delivery position direct a jet of gas or jet of water, respectively, to the center of the wafer.

7. The method of claim 1, wherein coating the active surface of the wafer with the film of water comprises flowing water at a flow rate of about 1.5 l/min.

8. The method of claim 2, wherein delivering water to the back surface of the wafer comprises flowing water at a flow rate of about 0.5 l/min.

9. The method of claim 1, wherein the water is delivered to the center of the wafer for a time between about 20 seconds and about 30 seconds.

10. The method of claim 1, wherein the wafers are cleaned at atmospheric pressure.

11. The method of claim 1, wherein a tracking device detects the wet-dry boundary and provides a feedback loop to move the gas nozzle in response to the moving wet-dry boundary.

12. The method of claim 1, wherein the gas is nitrogen.

13. The method of claim 1, wherein delivering the gas comprises flowing the gas at a flow rate between about 2 l/min and about 20 l/min.

14. An apparatus for cleaning wafers, the apparatus comprising:
a cleaning module comprising:
a water nozzle,
a gas nozzle,
a wafer holder for holding the wafer and rotating the wafer during cleaning, and
a tracking device oriented for detecting the wafer surface while the wafer is held and rotated on the wafer holder; and
a wafer imaging system comprising:
image analysis logic for detecting a wet-dry boundary on the wafer surface using optical properties of the surface, and
a feedback mechanism for moving the gas nozzle in response to data collected from the tracking device.

15. The apparatus of claim 14, wherein the cleaning apparatus is integrated with an etching apparatus, the etching apparatus comprising one or more process chambers for etching patterns on wafers and a wafer transfer tool.

16. The apparatus of claim 15, wherein the etching apparatus is a platform or cluster tool.

17. The apparatus of claim 14, wherein the optical properties comprise polarization.

18. The apparatus of claim 14, wherein the optical properties comprise reflection.

19. The apparatus of claim 14, wherein the optical properties comprise color and brightness.

20. The apparatus of claim 14, wherein the gas nozzle is pivoted from a point outside the edge of the wafer.

21. The apparatus of claim 14, wherein the water nozzle is pivoted from a point outside the surface of the wafer.
